(19) United States
(12) Patent Application Publication
(10) Pub. No.: US 2024/0183892 A1
(43) Pub. Date: Jun. 6, 2024

(54) CHARGE SENSOR

(71) Applicant: GUARDION, INC., Burlington, MA (US)

(72) Inventors: Daniel C. Cohen, Arlington, MA (US); Daniel M. Esposito, Nashua, NH (US)

(21) Appl. No.: 18/531,288

(22) Filed: Dec. 6, 2023

Related U.S. Application Data
(60) Provisional application No. 63/430,659, filed on Dec. 6, 2022.

(51) Int. Cl. G01R 29/24

(52) U.S. Cl. CPC G01R 29/24

(57) ABSTRACT

A charge-sensing apparatus includes a substrate, a first electrode and a second electrode, a channel layer disposed on the substrate and in electrical connection with the first electrode and the second electrode, and a charge storage layer disposed on or above the channel layer. A constant or time-varying voltage or current is applied across the first electrode and the second electrode, and one or more electrical properties of the channel layer is measured from a resulting current or voltage across the first electrode and the second electrode, which is correlated to the charges introduced into the charge storage layer.

### CROSS-REFERENCE TO RELATED APPLICATION(S)

This application claims priority from Provisional Application No. 63/430,659 filed Dec. 6, 2022, which is incorporated herein by reference in its entirety.

### STATEMENT REGARDING FEDERALLY SPONSORED RESEARCH OR DEVELOPMENT

This invention was made with government support under Award Number 2026087 awarded by the National Science Foundation. The government has certain rights in the invention.

### TECHNICAL FIELD

The present disclosure relates to a charge sensor, and more particularly, to a charge sensor that quantifies electric charges with excellent amplification characteristics, low power consumption, rapid resetting capabilities, and ambient condition compatibility, which has various applications including, but not limited to, mass spectrometers, residual gas analyzers, vacuum gauges, photon sensors, and radiation sensors/detectors.

### RELATED ART

Charge sensors are used in various applications. For example, mass spectrometers such as a laser desorption mass spectrometer, a time of flight (ToF) mass spectrometer, and an ion mobility spectrometer utilize charge-sensing technologies for measurement of ions. The charge-sensing technologies are also critical in vacuum pressure measurement, ionizing radiation detection, corona arc sensing, detection of charged particles in accelerators, space-based experiments, and the like.

Further, electron sensing instruments and techniques such as an electrometer, a scanning electron microscope (SEM), a transmission electron microscope, an electron energy loss spectrometer, an X-ray/UV photoelectron spectrometer (XPS/UPS), and angle-resolved photoemission spectroscopy (ARPES) also rely on charge sensors.

Existing charge sensors rely on electron multipliers or charge collecting plates coupled with semiconductor transimpedance amplifiers. There are several limitations to existing charge-sensing technologies. For example, electron multipliers require high voltage and high vacuum, and also require channels or dynodes that are fragile and bulky. Charge-sensing technologies based on semiconducting amplifiers have higher detection limits and hence are less useful for low-level detection.

To advance these fields, low-power charge sensors with high intrinsic charge-to-current (or charge-to-voltage) amplification are desirable.

### SUMMARY

Aspects of the present disclosure provide charge sensors that quantify electric charges on a conductor or a dielectric that modulates the electrical properties of a nanomaterial film, where a change in current or voltage across the nanomaterial is an amplified function of the charge accumulated. According to the charge sensors of the present disclosure, excellent amplification characteristics, low power consumption, and rapid resetting capabilities can be achieved.

According to an aspect of the present disclosure, an apparatus may include a substrate, a first electrode and a second electrode, a channel layer disposed on the substrate and in electrical connection with the first electrode and the second electrode, and a charge storage layer disposed on or above the channel layer. In particular, one or more charges introduced on the charge storage layer may be configured to alter one or more electrical properties of the channel layer. The following features may be included alone or in any combination.

In some embodiments, the charge storage layer may include a dielectric layer. By way of example, the dielectric layer may include Al₂O₃, SiO₂, Si₃N₄, ZrO₂, HfO₂, TiO₂, SrTiO₃, CaTiO₃, SiC, GaN, TiO₂, ZnO, diamond, fullerene, BN, Be₃N₂, AlP, AlAs, AlGaN, GaP, CdS, ZnSe, ZnS, ZnTe, CuzO, SnO₂, polydimethylsiloxane (PDMS), polymethyl methacrylate (PMMA), polyethylene terephthalate (PET), polyethylene (PE), polypropylene (PP), or any combination thereof. A thickness of the dielectric layer may be equal to or less than about 200 nm, about 150 nm, about 100 nm, about 50 nm, about 25 nm, about 10 nm, about 5 nm, or about 2 nm.

In some embodiments, the charge storage layer may include a light-sensitive material, which becomes conductive in response to one or more photons being incident thereto. By way of example, the light-sensitive material may include SiC, TiO₂, ZnO, GaO, P3HT, MEH-PPV, semiconducting polymers, diamond, fullerene, BN, AlP, AlAs, GaN, AlGaN, InGaN, InAlGaN, InN, InP, InO, InSb, GaP, CdS, CdSe, ZnSe, ZnS, ZnTe, Cu₂O, SnO₂, InGaAs, GaAs, InAs, Ge, InGaAs, PbS, PbTe, PbSe, Ge, Si, or any combination thereof.

Further, the one or more charges on the charge storage layer may be configured to be removed via heat, ultraviolet (UV) light, oppositely charged ions, electron or hole tunneling, or electron beams.

In some embodiments, the charge storage layer may include an upper dielectric layer disposed on the channel layer, and a third electrode disposed on the upper dielectric layer. In some such embodiments, the third electrode may be electrically connected to an external source and/or a collector of the one or more charges.

In some embodiments, the third electrode may be configured to be reset by being connected to a predetermined voltage via a switch. One or more charges may be removed or added to the third electrode by applying the predetermined voltage. The predetermined voltage may be a ground voltage. In some embodiments, the switch may be implemented as a transistor such as a junction field effect transistor or a tunneling field effect transistor. In some embodiments, the switch may be implemented as a physical switch such as a reed relay. For the resetting function, a reset electrode and a tunneling dielectric, which is disposed between the third electrode and the reset electrode, may be included. The predetermined voltage may be set on the reset electrode to cause electric charges to tunnel between the reset electrode and the third electrode across the dielectric and to neutralize the charges on the third electrode, thereby resetting the third electrode.

The substrate may include a lower dielectric layer that is disposed under the channel layer. The substrate may further include a conductive or semiconductive layer disposed under the lower dielectric layer. The conductive or semiconductive layer may be subject to a predetermined voltage. By way of example, the predetermined voltage may be a ground potential.

In some embodiments, the apparatus may further include a dielectric encapsulation layer disposed over the first electrode and the second electrode to insulate them from the one or more charges. In some embodiments, the dielectric encapsulation layer may cover substantially an entire area of the substrate. In some embodiments, the dielectric encapsulation layer may not cover the channel layer. The apparatus may further include a conductive layer disposed on the dielectric encapsulation layer to provide electrical grounding.

The one or more charges introduced on the charge storage layer may be configured to induce charges in the channel layer, thereby altering the one or more electrical properties thereof.

In operations, a constant or time-varying voltage may be applied across the first electrode and the second electrode, and a resulting current may be measured across the first electrode and the second electrode to detect a change in the one or more electrical properties of the channel layer. Accordingly, the one or more charges introduced on the charge storage layer may be quantified based on the change in the one or more electrical properties of the channel layer.

In some implementations, a constant or time-varying current may be applied across the first electrode and the second electrode, and a resulting voltage may be measured across the first electrode and the second electrode to detect a change in the one or more electrical properties of the channel layer. Accordingly, the one or more charges introduced on the charge storage layer may be quantified based on the change in the one or more electrical properties of the channel layer.

In some embodiments, the channel layer may be formed of a metallic, semi-metallic, or semiconductor material. In some such embodiments, the channel layer may be formed of a nanomaterial. By way of example, the nanomaterial may include graphene, single-walled carbon nanotube (SWNT), semiconductor SWNT, metallic SWNT, mixed SWNT, multi-walled carbon nanotube (MWNT), semiconductor MWNT, metallic MWNT, mixed MWNT, semiconductor nanowires (e.g., silicon nanowires, gallium nitride nanowires, or the like), silicon (Si), graphdiyne, borophene, silicene, MoS₂, WS₂, MoSe₂, WSe₂, MoTe₂, MXene, or any combination thereof.

Further, the one or more charges may occur due to addition or removal of an electron, a positive ion, a negative ion, a photon, or any combination thereof; or due to a radioactive, nuclear, chemical, electrochemical, photochemical, and/or photoelectrochemical process resulting in charged particles.

To quantify radiation, in some embodiments, the apparatus may further include an anode and a cathode such that, in response to one or more photons being incident to the apparatus, the cathode is positively charged, and electrons liberated from the cathode are captured by the anode. To this end, in some embodiments, the cathode may have a greater radiation interaction cross-section than the anode. In some other embodiments, a window may be formed in the anode such that the photons can directly interact with the cathode, and the electrons emitted from the cathode can be received by the anode. In such embodiments, the anode may not necessarily have a smaller radiation interaction cross-section than the cathode. Further, the cathode may be electrically connected to the charge storage layer to allow the charge storage layer to become positively charged, or the anode may be electrically connected to the charge storage layer to allow the charge storage layer to become negatively charged, which may be quantified based on a change in the one or more electrical properties of the channel layer.

In some embodiments, the apparatus may further include a charge collector that is in electrical connection with the charge storage layer to receive the one or more charges and transmit the charges to the charge storage layer. The charge collector may be provided separately from the apparatus while being in electrical connection.

In some implementations, the upper dielectric layer may be sensitive to UV light. By way of example, the UV-sensitive upper dielectric layer may include SiC, TiO₂, ZnO, GaO, P3HT, MEH-PPV, semiconducting polymers, diamond, fullerene, BN, AlP, AlAs, GaN, AlGaN, InGaN, InAlGaN, GaP, CdS, CdSe, CdTe, ZnSe, ZnS, ZnTe, Cu₂O, or any combination thereof.

In some implementations, the upper dielectric layer may be sensitive to infrared (IR) light. By way of example, the IR-sensitive upper dielectric layer may include InN, InP, InO, InSb, SnO₂, InGaAs, GaAs, GaSb, InAs, Ge, InGaAs, PbS, PbTe, PbSe, Ge, Si, or any combination thereof.

In some embodiments, an area of the third electrode may be larger than an area of the channel layer.

In a related aspect of the present disclosure, an apparatus may include a substrate, a lower dielectric layer disposed on the substrate, a channel layer disposed on the lower dielectric layer, a first electrode and a second electrode that are in electrical connection with both ends of the channel layer, and a back electrode disposed between the substrate and the lower dielectric layer. In particular, the back electrode may be electrically connected to an external source of one or more charges, and the one or more charges introduced on the back electrode may be configured to alter one or more electrical properties of the channel layer. Accordingly, the one or more charges on the back electrode may be quantified based on a change in the one or more electrical properties of the channel layer.

In related aspects, an electrometer, a memory device, or a time-tracking device may be implemented based on the apparatus described herein.

In another aspect of the present disclosure, a method of quantifying ion flux using an apparatus, which includes a first electrode, a second electrode, a channel layer electrically connected between the first electrode and the second electrode, and a charge storage layer disposed over the channel layer, may include allowing one or more charges to be introduced on the charge storage layer due to the ion flux, applying a voltage or a current between the first electrode and the second electrode, and measuring a change in one or more electrical properties of the channel layer caused by the one or more charges on the charge storage layer, thereby quantifying the ion flux.

The following features may be included alone or in any combination.

In some embodiments, a method of quantifying electron flux, using an apparatus that includes a first electrode, a second electrode, a channel layer electrically connected between the first electrode and the second electrode, and a charge storage layer disposed over the channel layer, may include allowing one or more charges to be introduced on the charge storage layer due to the electron flux, applying a voltage or a current between the first electrode and the second electrode, and measuring a change in one or more electrical properties of the channel layer caused by the one or more charges on the charge storage layer, thereby quantifying the electron flux.

In some embodiments, a method of quantifying photon flux, using an apparatus that includes a first electrode, a second electrode, and channel layer electrically connected between the first electrode and the second electrode, and a charge storage layer disposed over the channel layer, may include allowing one or more charges to be introduced on the charge storage layer due to electrons ejected by photoelectric effect caused by the photon flux, applying a voltage or a current between the first electrode and the second electrode, measuring a change in one or more electrical properties of the channel layer caused by the one or more charges on the charge storage layer, thereby quantifying the one or more charges, and quantifying the photon flux based on photoelectric quantum yield.

The charge sensor according to the present disclosure can provide a high amplification with a low power consumption, for example, using a driving voltage of about an order of 0.1 V. The charge sensor according to the present disclosure can eliminate the high voltage requirements, reduce power consumption, and work in atmospheric conditions without requiring a vacuum pump. The charge sensor according to embodiments of the present disclosure allows the sensing of a wide variety of analytes including ions, electrons, photons, and ionizing radiation based on their charging behaviors. Further, the charge sensor according to the present disclosure can function in vacuum to ambient pressures, and also at above-ambient pressures, and detect both positive and negative ions, electrons, photons, and ionizing radiation.

### BRIEF DESCRIPTION OF THE DRAWINGS

A brief description of each drawing is provided for more sufficient understanding of the drawings used in the detailed description of the present disclosure.

FIG. 1 schematically shows a charge sensor and a scheme to quantify the charge according to embodiments of the present disclosure;

FIG. 2 schematically shows an embodiment of a charge sensor according to the present disclosure and manufacturing steps thereof;

FIG. 3 schematically shows a related embodiment of a charge sensor according to the present disclosure and manufacturing steps thereof;

FIG. 4 schematically shows another related embodiment of a charge sensor according to the present disclosure and manufacturing steps thereof;

FIG. 5A schematically shows an embodiment of a charge sensor with a reset switch according to the present disclosure;

FIG. 5B shows a circuit diagram for the embodiment of FIG. 5A;

FIG. 5C schematically shows an embodiment of a reset switch implemented as a tunneling dielectric and an electrode according to the present disclosure;

FIG. 6 schematically shows an embodiment of an electrometer based on a charge sensor according to the present disclosure;

FIG. 7A schematically shows an embodiment of a memory device based on a charge sensor according to the present disclosure;

FIG. 7B illustrates switching operations for the memory device of FIG. 7A;

FIG. 8 schematically shows an embodiment of a passive time-tracking device based on a charge sensor according to the present disclosure;

FIG. 9A illustrates a photon sensor based on a charge sensor according to an embodiment of the present disclosure, where the photon-sensing members are remotely provided and in electrical connection with the top electrode;

FIG. 9B illustrates a photon sensor based on a charge sensor according to an embodiment of the present disclosure, where the photon-sensing cathode is integrally provided with the top electrode;

FIG. 9C illustrates a photon sensor based on a charge sensor according to an embodiment of the present disclosure, where a window is formed in the anode;

FIGS. 10A and 10B schematically show embodiments of a UV dosimeter based on a photon sensor configuration according to the present disclosure;

FIG. 11 schematically shows a related embodiment of a UV dosimeter based on a charge sensor according to the present disclosure;

FIG. 12 schematically shows an embodiment of an IR and/or other wavelength dosimeter based on a charge sensor according to the present disclosure;

FIGS. 13A-13C schematically show another related embodiment of a charge sensor according to the present disclosure;

FIG. 14 shows experimental results for measuring the current response of a charge sensor according to the present disclosure using alternating corona discharge ion sources;

FIG. 15 shows experimental results for measuring the current response of a charge sensor with a separate charge collector connected to the top electrode according to the present disclosure using corona discharge ion sources;

FIG. 16 shows experimental results for measuring the current response of a charge sensor according to the present disclosure to ions and electrons inside a vacuum chamber, using a controlled charge source;

FIG. 17 shows experimental results comparing the current responses to positive ion flux of charge sensors according to the present disclosure with the measured ion current; and

FIG. 18 compares experimental results from a mass spectrometer using a charge sensor according to the present disclosure and a built-in electron multiplier.

It should be understood that the above-referenced drawings are not necessarily to scale, presenting a somewhat simplified representation of various features illustrative of the basic principles of the disclosure. The specific design features of the present disclosure, including, for example, specific dimensions, orientations, locations, shapes, and manufacturing steps, will be determined in part by the particular intended application and use environment.

### DETAILED DESCRIPTION

Advantages and features of the present disclosure and a method of achieving the same will become apparent with reference to the accompanying drawings and exemplary embodiments described below in detail. However, the present disclosure is not limited to the exemplary embodiments described herein and may be embodied in variations and modifications thereof. The exemplary embodiments are provided merely to allow one of ordinary skill in the art to understand the scope of the present disclosure, which will be defined by the scope of the claims. Accordingly, in some embodiments, well-known operations of a process, well-known structures, and well-known technologies will not be described in detail to avoid obscuring the disclosure. Throughout the specification, same reference numerals refer to same elements.

The terminology used herein is for the purpose of describing particular embodiments only and is not intended to limit the disclosure. As used herein, the singular forms “a,” “an” and “the” are intended to include the plural forms thereof as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is to be understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

The present disclosure provides a charge sensor that captures charges on a conductor or a dielectric that influences one or more electrical properties of an underlying nanomaterial film, where a change in current or voltage across the nanomaterial is an amplified function of the captured charges. The charge sensor according to embodiments of the present disclosure can be implemented as a charge-to-current amplifier, a charge-to-voltage amplifier, or a charge integrator. The charge sensor according to the present disclosure can be utilized in various fields such as spectroscopy, chemical and material analysis, microscopy, residual gas analysis, semiconductor manufacturing, drug discovery, countering weapons of mass destruction, and the like.

The charge sensor according to the present disclosure can replace electron multipliers and photomultiplier tubes in various applications and instruments as it can provide a high amplification with a low power consumption, for example, using a driving voltage of about 0.1V. The charge sensor according to the present disclosure can eliminate the high voltage requirements, reduce power consumption, and work in wide pressure ranges without requiring a vacuum pump. The charge sensor according to embodiments of the present disclosure allows the sensing of a wide variety of analytes including ions, electrons, photons, and ionizing radiation based on their charging behaviors. Further, the charge sensor according to the present disclosure can function in vacuum to ambient pressures and detect both positive and negative ions, electrons, photons, and ionizing radiation. The charge sensor according to the present disclosure can also function at above-ambient pressures. Herein, ionizing radiation may include, but is not limited to, x-ray, gamma-ray, alphas, betas, neutrons, muons, and quarks.

The charge sensor according to the present disclosure may be configured to detect UV-C emissions from a hypersonic flying object. For instance, gas molecules around a hypersonic projectile may be dissociated and ionized due to aerodynamic heating and may emit radiation in the UV-C wavelengths. Plumes from missile and rocket engines may be hot enough to emit radiation in the UV-C wavelengths. The UV-C emission from such hypersonic projectiles may be one of the rare sources of UV-C below the ozone layer. The charge sensors according to embodiments of the present disclosure may be developed as the UV-C detector that can detect the UV-C emitted from a hypersonic flying object while discriminating the solar radiation in the UV-A/B bands and visible light. Accordingly, the charge sensors can serve as a solar-blind UV-C detector for early warning systems and hypersonic object detection systems. By way of example, the UV-C radiation may have wavelengths from about 200 nm to about 280 nm.

In an aspect of the present disclosure, a top electrode may be formed of a metal to directly or indirectly collect electric charges, which can be amplified in a channel connected across a first electrode and a second electrode, resulting in a change in current or voltage therebetween. In some embodiments, the top electrode may float while sensing, and current or voltage between the first electrode and the second electrode through a nanomaterial film may be altered by an amplifying function of the collected charges.

In use, as the top electrode floats during the sensing, it may become highly charged and may need to be returned to a neutral or other desired charge state. Accordingly, a switch component may be provided to remove the collected charges from the top electrode and to reset the device for continued measurements. In some embodiments, the charges on the top electrode may be reset by applying a bias to the channel or another electrode separated from the top electrode by an insulating layer. Electrons may tunnel into or out of the top electrode to restore it to a desired charge state at which point the bias may be turned off. In some embodiments, tunneling may be implemented in a device that is electrically connected to the top electrode. In some such embodiments, the device may be implemented as a tunneling field effect transistor. The tunneling field effect transistor may be intrinsically implemented on the substrate or extrinsically provided using one or more external devices.

In the charge sensor according to the present disclosure, the transconductance as a function of voltage may be substantially linear within the dynamic range of the charge sensor while that of a semiconductor device is typically nonlinear. The voltage applied to the charge sensor is substantially linear as a function of collected charge, thereby maintaining a constant gain across the charge sensor's dynamic range. Thus, newly collected charges can produce the same signal regardless of the prior state of the sensor, which can eliminate the need to know the prior state of the sensor for measuring the amount of newly collected charges.

Due to the utilization of nanomaterial films, the charge sensor according to embodiments of the present disclosure provides unique features. For example, unlike bipolar junction transistors (BJTs) and other current-controlled transistors that rely on a current flow through a base, the top electrode of the charge sensor according to embodiments of the present disclosure floats, and the build-up charge on the top electrode can be quickly discharged. Further, while voltage-controlled junction-gate field-effect transistors (JFETs) having a PN or NP junction on the gate have finite reverse leakage and therefore can easily enter a saturation region (also known as a “pinch off”), the charge sensor according to the present disclosure can have a broader dynamic range as well as a resetting capability. Also, while metal-oxide-semiconductor field-effect transistors (MOSFETs) have a gate-oxide-channel structure that only strongly amplifies one polarity of charge on the gate and has different regimes of amplification based on gate-source voltage, threshold voltage, and source-drain voltage, the charge sensor according to embodiments of the present disclosure can respond to both positive and negative charges with substantially equal amplification, allowing for detection of both polarity of ions, as well as electron detection and photon detection. Furthermore, while the MOSFETs require that a threshold voltage be applied to a top gate to allow a current between a source and a drain, the charge sensor according to the present disclosure can detect from the first incident charge, and accordingly, a greater dynamic range can be achieved without sacrificing the high flux responses.

Further, in some embodiments, the top electrode of the charge sensor according to the present disclosure can detect vapor-phase ions and electrons. In some embodiments, the charge sensor according to the present disclosure can be placed outside a charge source, for example, using a remote charge collector that is in electrical connection with the top electrode. In some embodiments, the charge sensor can detect photons or ionizing radiation, for example, via the photoelectric effect.

Furthermore, the charge-sensing devices according to the present disclosure can be typically fabricated based on photolithography, and thus can be pixelated and made into 1D or 2D grid arrays to offer spatially resolved measurements and/or redundancy.

Hereinbelow, embodiments of the charge sensors according to the present disclosure will be described with reference to the appended drawings.

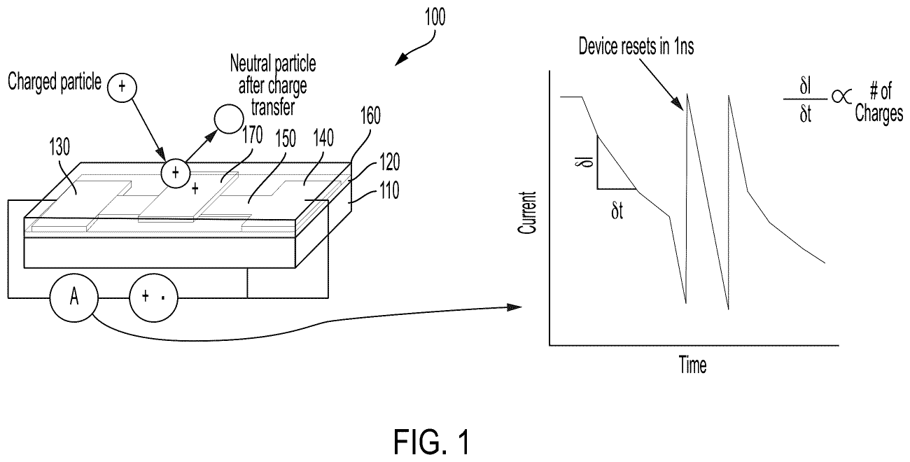

FIG. 1 schematically shows a charge sensor 100 and a scheme to quantify the charge according to an embodiment of the present disclosure. The charge sensor 100 apparatus may include a conductive substrate 110, and a first dielectric layer (hereinbelow also referred to as a lower dielectric layer) 120 disposed on the conductive substrate 110. A first electrode 130 and a second electrode 140 may be disposed on the first dielectric layer 120, and a channel layer 150 may electrically connect the first electrode 130 and the second electrode 140. Further, a second dielectric layer (hereinbelow also referred to as an upper dielectric layer) 160 may be disposed on the channel layer 150. In some embodiments, a third electrode (hereinbelow also referred to as a top electrode) 170 may be disposed on the second dielectric layer 160. In some embodiments, the conductive substrate 110 may serve as a fourth electrode (hereinbelow also referred to as a back electrode) and may be subject to a predetermined voltage, which may be, for example, a ground potential. By way of example, the fourth electrode 110 may be subjected to a voltage between about −10V and about +10V. Throughout the disclosure, directions such as top and bottom are given with reference to the orientation of the corresponding figure. The directions are not to be understood as absolute directions since the orientation of the devices can be changed. As such, the top electrode, as used herein, may be understood as a charge collecting electrode regardless of its position.

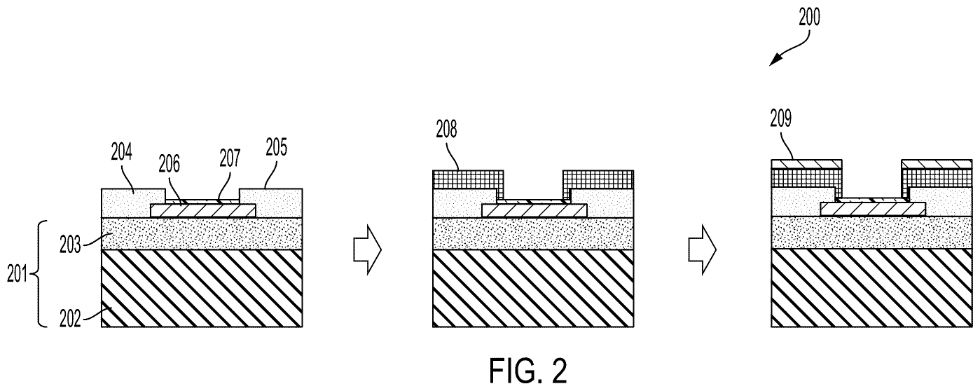

In operations, one or more charges may be introduced to the top electrode 170, and capacitive coupling may induce charges within the channel layer 150. In some embodiments (e.g., an embodiment shown in FIG. 2 to be described below), one or more charges may be introduced onto the surface of the second dielectric layer 160. In some such embodiments, the introduced charges may induce mirror charges within the channel layer 150. In order to quantify the one or more charges, a potential difference, constant or time-varying, or an electrical current, constant or time-varying, may be applied across the first electrode 130 and the second electrode 140, and a resulting current or voltage, respectively, may be measured between the first electrode 130 and the second electrode 140. By way of example, a DC voltage of about 10V or less may be applied between the first electrode 130 and the second electrode 140. For example, a DC voltage of about 5V, about 1V, about 0.5V, about 0.1V, or about 0.05V may be applied. Hereinbelow, the first electrode 130 and the second electrode 140 may also be referred to as a pair of drive electrodes.

The electric field between the top electrode 170 and the channel layer 150 that is generated due to the one or more charges collected on the top electrode 170 may induce a change in one or more electrical properties of the channel layer 150, and thus in the current flowing between the first electrode 130 and the second electrode 140 at a constant voltage. In turn, the change of the resulting current may be detected. To this end, a current meter may be provided and configured to measure the resulting current between the first electrode 130 and the second electrode 140. Consequently, the incident charges may be quantified based on the change of the resulting current measured between the first electrode 130 and the second electrode 140. In some implementations, to quantify the charge on the top electrode 170, a constant or time-varying current may be applied between the first electrode 130 and the second electrode 140, and a voltmeter may be used to monitor the voltage response across the channel. By way of example, the one or more electrical properties may include electrical resistance, impedance, or the like.

Herein, although an example of using a voltage source (constant or varying) applied across the first electrode 130 and the second electrode 140 and measuring the change in resultant current is mainly described, the present disclosure is not limited thereto. In some embodiments, a current source (constant or varying) may be applied across the first electrode 130 and the second electrode 140, and the change in resultant voltage between the first electrode 130 and the second electrode 140 may be measured to detect the changes in the resistance of the channel layer 150 and thereby to quantify the charges collected on the top electrode 170. In some embodiments, a time-varying current or voltage may be applied across the first electrode 130 and the second electrode 140, and the resulting voltage or current signal, respectively, may be measured. One or more frequencies may be chosen for the time-varying current or voltage, for example, to avoid noise in the circuit and/or interference by electromagnetic radiation.

FIGS. 2-4 schematically show embodiments of charge sensors according to the present disclosure and nominal manufacturing steps thereof. In the figures, the manufacturing steps are provided merely to describe each component and the relationship therebetween, and not to limit the fabrication methods for the devices. The actual fabrication or manufacturing of the devices can be carried out using various techniques in various sequences.

According to an embodiment of the charge sensor 200 shown in FIG. 2, a substrate 201 may include one or more materials that constitute a back electrode for gating the device while providing mechanical structure for the device. In particular, the substrate 201 may include a first dielectric layer 203 and may optionally include a conductive substrate 202 including P-doped or N-Doped Si. In some embodiments, the conductive substrate 202 may include graphite. By way of example, the first dielectric layer 203 may include Al₂O₃, SiO₂, Si₃N₄, ZrO₂, HfO₂, TiO₂, SrTiO₃, CaTiO₃, SiC, GaN, TiO₂, ZnO, diamond, fullerene, BN, Be₃N₂, AlP, AlAs, AlGaN, GaP, CdS, ZnSe, ZnS, ZnTe, Cu₂O, SnO₂, polydimethylsiloxane (PDMS), polymethyl methacrylate (PMMA), polyethylene terephthalate (PET), polyethylene (PE), polypropylene (PP), or any combination thereof.

On top of the first dielectric layer 203 of the substrate 201, a first electrode 204 and a second electrode 205 may be formed. By way of example, each of the first electrode 204 and the second electrode 205 may include gold (Au), chromium (Cr)/gold (Au) alloy, titanium (Ti)/gold (Au) alloy, aluminum (Al), palladium (Pd), platinum (Pt), titanium (Ti), copper (Cu), silver (Ag), nickel (Ni), titanium nitride (TiN), tin (Sn), zinc (Zn), chromium (Cr), silicon (Si), germanium (Gc), graphite, or any combination thereof.

A channel layer 206 may be formed on the first dielectric layer 203 and between the first electrode 204 and the second electrode 205. By way of example, metallic, semi-metallic, semiconductor 2D material film, a network thereof, or the like may be used for the channel layer 206. In some embodiments, graphene, single-walled carbon nanotube (SWNT), semiconductor SWNT, metallic SWNT, mixed SWNT, multi-walled carbon nanotube (MWNT), semiconductor MWNT, metallic MWNT, mixed MWNT, semiconductor nanowires (e.g., silicon nanowires, gallium nitride nanowires, or the like), silicon (Si), graphdiyne, borophene, silicene, MoS₂, WS₂, MoSe₂, WSe₂, MoTe₂, MXene, or any combination thereof may be used for the channel layer 206. Herein, the channel layer of any embodiments of the present disclosure may be a monolayer, a bi-layer, or have 3, 4, 5, 6, 7, 8, 9, 10 layers or more. Carbon nanotube channels may have single-walled, double-walled, or multi-walled tubes.

A second dielectric layer 207 may be disposed on the channel layer 206. In this embodiment, the second dielectric layer 207 may adsorb ions and/or charges from incident ions, electrons, or photons, and may include a material that can be made conductive by incident photons, magnetic fields, electrical fields, and/or temperature to allow release of the adsorbed ions and/or charges. By way of example, Al₂O₃, SiO₂, Si₃N₄, ZrO₂, HfO₂, TiO₂, SrTiO₃, CaTiO₃, SiC, GaN, TiO₂, ZnO, diamond, fullerene, BN, Be₃N₂, AlP, AlAs, AlGaN, GaP, CdS, ZnSe, ZnS, ZnTe, Cu₂O, SnO₂, PDMS, PMMA, PET, PE, PP, or any combination thereof may be used as the second dielectric layer 207.

Further, a dielectric encapsulation layer 208 may be disposed over the first electrode 204 and the second electrode 205, while at least some portion of the second dielectric layer 207 may remain open through the dielectric encapsulation layer 208 for charge collection. The dielectric encapsulation layer 208 may be added to enhance mechanical strength, adhesion, and/or to prevent the charges from being incident on electrodes. By way of example, Al₂O₃, SiO₂, Si₃N₄, ZrO₂, HfO₂, TiO₂, SrTiO₃, CaTiO₃, SiC, GaN, TiO₂, ZnO, diamond, fullerene, BN, Be₃N₂, AlP, AlAs, AlGaN, GaP, CdS, ZnSe, ZnS, ZnTe, Cu₂O, SnO₂, PDMS, PMMA, PET, PE, PP, or any combination thereof may be used as the dielectric encapsulation layer 208.

In some embodiments, a conductive cover layer 209 may be disposed on the dielectric encapsulation layer 208 to prevent the charges from building up in the dielectric encapsulation layer 208 due to biasing, grounding, or the like. By way of example, Au, Cr—Au alloy, Ti—Au alloy, Al, Pd, Pt, Ti, Cu, Ag, Ni, TiN, Sn, Zn, Cr, Si, Ge, graphite, or any combination thereof may be used for the conductive cover layer 209.

In the embodiment shown in FIG. 2, without intending to be bound by any particular theory, as charges are incident on the second dielectric layer 207, mirror charges may be induced within the channel layer 206. Accordingly, resulting resistance of the channel layer 206 may be changed, which in turn may be quantified by measuring the current or voltage response between the first electrode 204 and the second electrode 205.

In some embodiments, the second dielectric layer 207 may include a material that can be made conductive such that the charges that have been introduced on the second dielectric layer 207 may be neutralized when the second dielectric layer 207 is made conductive. In some embodiments, to neutralize the second dielectric layer 207, opposite charges may be introduced to the second dielectric layer 207. Further, the charges on the second dielectric layer 207 may be removed via heat, UV light, oppositely charged ions, electron or hole tunneling, and/or electron beams.

The thickness of the second dielectric layer 207 may be equal to or less than about 1 μm. In some embodiments, the thickness of the second dielectric layer 207 may be equal to or less than about 200 nm. By way of example, the thickness of the second dielectric layer 207 may be about 900 nm, about 800 nm, about 700 nm, about 600 nm, about 500 nm, about 400 nm, about 300 nm, about 200 nm, about 190 nm, about 180 nm, about 170 nm, about 160 nm, about 150 nm, about 140 nm, about 130 nm, about 120 nm, about 110 nm, about 100 nm, about 90 nm, about 80 nm, about 70 nm, about 60 nm, about 50 nm, about 40 nm, about 30 nm, about 20 nm, about 10 nm, about 5 nm, or about 2 nm.

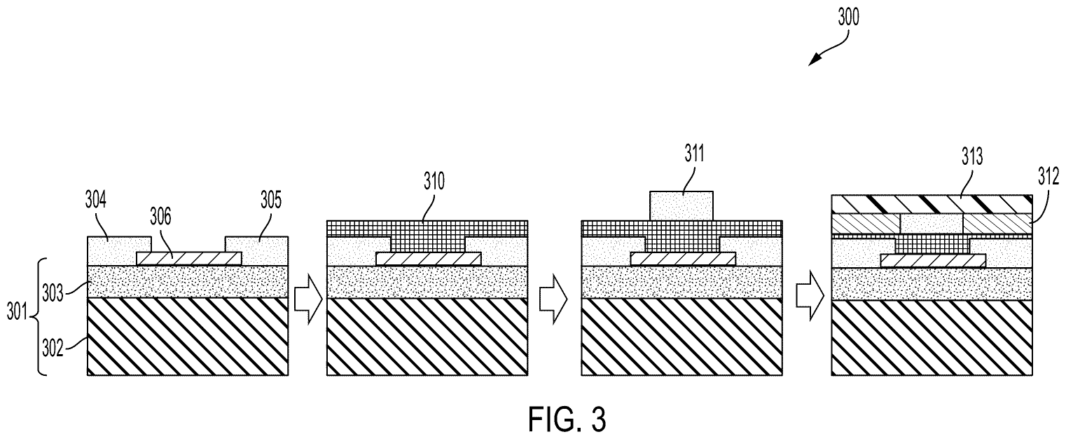

According to an embodiment of the charge sensor 300 shown in FIG. 3, a substrate 301 may include one or more materials that constitute a back electrode for gating the device while providing mechanical structure for the device. In particular, the substrate 301 may include a first dielectric layer 303 and optionally a conductive substrate 302 including P-doped or N-Doped Si, and/or graphite. By way of example, the first dielectric layer 303 may include Al₂O₃, SiO₂, Si₃N₄, ZrO₂, HfO₂, TiO₂, SrTiO₃, CaTiO₃, SiC, GaN, TiO₂, ZnO, diamond, fullerene, BN, Be₃N₂, AlP, AlAs, AlGaN, GaP, CdS, ZnSe, ZnS, ZnTe, Cu₂O, SnO₂, PDMS, PMMA, PET, PE, PP, or any combination thereof.

On top of the first dielectric layer 303 of the substrate 301, a first electrode 304 and a second electrode 305 may be formed. By way of example, each of the first electrode 304 and the second electrode 305 may include Au, Cr—Au alloy, Ti—Au alloy, Al, Pd, Pt, Ti, Cu, Ag, Ni, TiN, Sn, Zn, Cr, Si, Ge, graphite, or any combination thereof.

A channel layer 306 may be formed on the first dielectric layer 303 and between the first electrode 304 and the second electrode 305. By way of example, metallic, semi-metallic, semiconductor 2D material film, a network thereof, or the like may be used for the channel layer 306. In some embodiments, graphene, SWNT, semiconductor SWNT, metallic SWNT, mixed SWNT, MWNT, semiconductor MWNT, metallic MWNT, mixed MWNT, semiconductor nanowires (e.g., silicon nanowires, gallium nitride nanowires, or the like), Si, graphdiyne, borophene, silicene, MoS₂, WS₂, MoSe₂, WSe₂, MoTe₂, MXene, or any combination thereof may be used for the channel layer 306.

A second dielectric layer 310 may be disposed on the channel layer 306. By way of example, Al₂O₃, SiO₂, Si₃N₄, ZrO₂, HfO₂, TiO₂, SrTiO₃, CaTiO₃, SiC, GaN, TiO₂, ZnO, diamond, fullerene, BN, Be₃N₂, AlP, AlAs, AlGaN, GaP, CdS, ZnSe, ZnS, ZnTe, Cu₂O, SnO₂, PDMS, PMMA, PET, PE, PP, or any combination thereof may be used as the second dielectric layer 310. In this embodiment, the second dielectric layer 310 may also cover the first electrode 304 and the second electrode 305 as well as the channel layer 306. As such, the second dielectric layer 310 may serve as a dielectric encapsulation layer 312 as well.

A top electrode 311 may be disposed on the second dielectric layer 310. In this embodiment, due to the second dielectric layer 310, the top electrode 311 may be electrically insulated from the channel layer 306 (i.e., “floating”), and may be used to capture incident charges. The charges captured in the top electrode 311 may induce charges within the channel layer 306 due to capacitive coupling and may generate an electric field between the top electrode 311 and the channel layer 306, thereby altering one or more electrical properties (e.g., resistance) of the channel layer 306.

In some embodiments, the top electrode 311 may be formed substantially larger than the channel layer 306 in order to facilitate “charge funneling,” which may change the one or more electrical properties of the channel layer 306 more effectively while minimally interacting with other electrodes and conductors. A larger top electrode 311 may interact with greater flux of charged particles or other analytes of interest including photons while storing the resulting charge on a capacitor formed with a smaller channel layer 306.

The first conductive layer 302 (which serves as a “back electrode”) may be grounded or biased to a predetermined voltage to change the conductivity of the channel layer 306 before collecting the charges. Without intending to be bound by any particular theory, subjecting the first conductive layer 302 to the predetermined bias voltage (e.g., a ground voltage) may improve the sensitivity of the apparatus, extend the dynamic range, improve linearity of the response, and/or allow non-linear behavior to be tuned for optimal performance of the apparatus.

By applying a voltage or a current (constant or varying) across the first electrode 304 and the second electrode 305 and measuring resultant current or voltage therebetween, the charges collected in the top electrode 311 may be quantified. By way of example, Au, Cr—Au alloy, Ti—Au alloy, Al, Pd, Pt, Ti, Cu, Ag, Ni, TiN, Sn, Zn, Cr, Si, Ge, graphite, or any combination thereof may be used as the top electrode 311.

Further, to prevent the charges from building up in the dielectric encapsulation layer 312 due to biasing, grounding, or the like, and/or to provide an electrical lead for resetting the top electrode 311, which will be described in more details later below, a conductive cover layer 313 may be disposed over the dielectric encapsulation layer 312. For the conductive cover layer 313, Au, Cr—Au alloy, Ti—Au alloy, Al, Pd, Pt, Ti, Cu, Ag, Ni, TiN, Sn, Zn, Cr, Si, Ge, graphite, or any combination thereof may be used. In some embodiments, the conductive cover layer 313 may be formed integrally with the top electrode 311, which may allow a greater number of charges to be collected at a given flux and may increase the total charges that are collected (e.g., “charge funneling”).

The embodiments shown in FIGS. 2 and 3 describe that the charges may be collected and/or at least temporarily stored within the second dielectric layer 207 (FIG. 2) or at the interface between the top electrode 311 and the second dielectric layer 310 (FIG. 3) such that the collected charges influence the electrical properties of the channel layer. Accordingly, these components may be herein collectively referred to as a “charge storage layer,” which may be understood to include a dielectric layer, an electrode (e.g., a top electrode), or both.

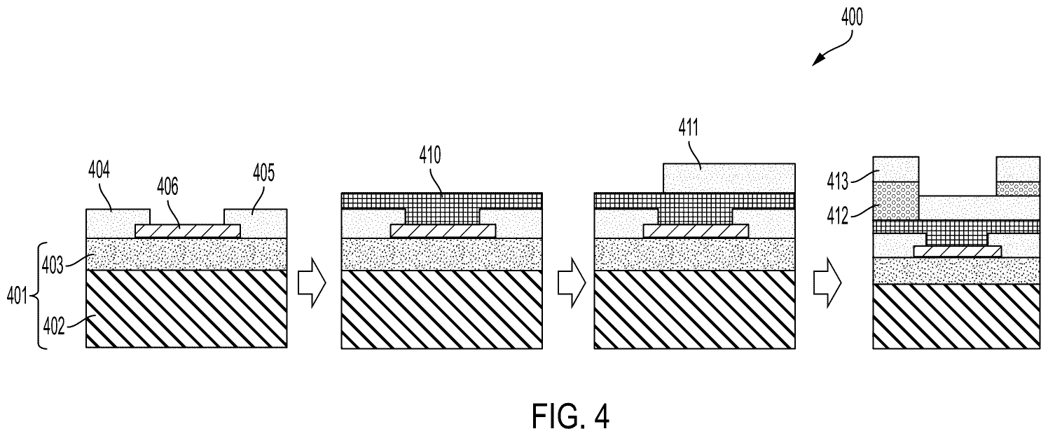

According to an embodiment of the charge sensor 400 shown in FIG. 4, a substrate 401 may include one or more materials that constitute a back electrode for gating the device while providing mechanical structure for the device. In particular, the substrate 401 may include a first dielectric layer 403 and optionally a conductive substrate 402 including P-doped or N-Doped Si, and/or graphite. By way of example, the first dielectric layer 403 may include Al₂O₃, SiO₂, Si₃N₄, ZrO₂, HfO₂, TiO₂, SrTiO₃, CaTiO₃, SiC, GaN, TiO₂, ZnO, diamond, fullerene, BN, Be₃N₂, AlP, AlAs, AlGaN, GaP, CdS, ZnSe, ZnS, ZnTe, Cu₂O, SnO₂, PDMS, PMMA, PET, PE, PP, or any combination thereof.

On top of the first dielectric layer 403, a first electrode 404 and a second electrode 405 may be formed. By way of example, each of the first electrode 404 and the second electrode 405 may include Au, Cr—Au alloy, Ti—Au alloy, Al, Pd, Pt, Ti, Cu, Ag, Ni, TiN, Sn, Zn, Cr, Si, Ge, graphite, or any combination thereof.

A channel layer 406 may be formed on the first dielectric layer 403 and between the first electrode 404 and the second electrode 405. By way of example, metallic, semi-metallic, semiconductor 2D material film, a network thereof, or the like may be used for the channel layer 406. In some embodiments, graphene, SWNT, semiconductor SWNT, metallic SWNT, mixed SWNT, MWNT, semiconductor MWNT, metallic MWNT, mixed MWNT, semiconductor nanowires (e.g., silicon nanowires, gallium nitride nanowires, or the like), Si, graphdiyne, borophene, silicene, MoS₂, WS₂, MoSe₂, WSe₂, MoTe₂, MXene, or any combination thereof may be used for the channel layer 406.

A second dielectric layer 410 may be disposed on the channel layer 406. By way of example, Al₂O₃, SiO₂, Si₃N₄, ZrO₂, HfO₂, TiO₂, SrTiO₃, CaTiO₃, SiC, GaN, TiO₂, ZnO, diamond, fullerene, BN, Be₃N₂, AlP, AlAs, AlGaN, GaP, CdS, ZnSe, ZnS, ZnTe, Cu₂O, SnO₂, PDMS, PMMA, PET, PE, PP, or any combination thereof may be used as the second dielectric layer 410. In this embodiment, the second dielectric layer 410 may also cover the first electrode 404 and the second electrode 405 as well as the channel layer 406.

A top electrode 411 may be disposed adjacent (e.g., on or over) the second dielectric layer 410. Similar to the embodiment shown in FIG. 3, due to the second dielectric layer 410, the top electrode 411 may be electrically insulated from the channel layer 406 (i.e., “floating”), and may be used to capture incident charges. The charges captured in the top electrode 411 may cause charges to be induced in the channel layer 406 due to capacitive coupling. The first conductive layer 402 (which serves as a “back electrode”) may be grounded or biased to change the conductivity of the channel layer 406 before collecting the charges. By way of example, the bias voltage may be between about −10V and about +10V.

By driving the first electrode 404 and the second electrode 405 with a constant or time-varying voltage and measuring resultant current therebetween, the charges collected in the top electrode 411 may be quantified. Throughout the specification, and in any embodiments disclosed herein, the charges collected in the top electrode may be quantified by applying a constant or varying voltage across the first electrode and the second electrode and measuring the resultant current therebetween; or by applying a constant or varying current across the first electrode and the second electrode and measuring the resultant voltage therebetween. When a time-varying voltage or current is applied, the change in one or more electrical properties of the channel layer may also be characterized via the impedance, frequency response, phase shift, or the like, in addition or alternative to the current and voltage response.

By way of example, Au, Cr—Au alloy, Ti—Au alloy, Al, Pd, Pt, Ti, Cu, Ag, Ni, TiN, Sn, Zn, Cr, Si, Ge, graphite, or any combination thereof may be used as the top electrode 411. In this embodiment, to facilitate resetting the top electrode 411, the top electrode 411 may be extended to cover one of the first electrode 404 or the second electrode 405 over the second dielectric layer 410.

Further, a dielectric encapsulation layer 412 may be disposed over the first electrode 404 and the second electrode 405. Due to the configuration that the top electrode 411 is extended over one of the first electrode 404 or the second electrode 405, the dielectric encapsulation layer 412 may be disposed on the second dielectric layer 410 on one electrode side, and on the extended portion of the top electrode 411 on the other electrode side. For example, where the top electrode 411 is extended over the second electrode 405, as shown in FIG. 4, the dielectric encapsulation layer 412 may be disposed on the second dielectric layer 410 in the first electrode 404 side and on the extended portion of the top electrode 411 in the second electrode 405 side. The dielectric encapsulation layer 412 may be added to enhance mechanical strength, adhesion, and/or to prevent the charges from being incident on electrodes. By way of example, Al₂O₃, SiO₂, Si₃N₄, ZrO₂, HfO₂, TiO₂, SrTiO₃, CaTiO₃, SiC, GaN, TiO₂, ZnO, diamond, fullerene, BN, Be₃N₂, AlP, AlAs, AlGaN, GaP, CdS, ZnSe, ZnS, ZnTe, Cu₂O, SnO₂, PDMS, PMMA, PET, PE, PP, or any combination thereof may be used as the dielectric encapsulation layer 412.

In some embodiments, the extended portion of the top electrode 411 may not be aligned with the longitudinal direction of the channel layer 406. For example, the extended portion of the top electrode 411 may be oriented substantially perpendicular to the longitudinal direction of the channel layer 406 in the 2D planform view. In such configurations, the dielectric encapsulation layer 412 may be disposed on the second dielectric layer 410 over both the first electrode 404 side and the second electrode 405 side.

Further, to prevent the charges from building up in the dielectric encapsulation layer 412 due to biasing, grounding, or the like, a conductive cover layer 413 may be disposed over the dielectric encapsulation layer 412. For the conductive cover layer 413, Au, Cr—Au alloy, Ti—Au alloy, Al, Pd, Pt, Ti, Cu, Ag, Ni, TiN, Sn, Zn, Cr, Si, Ge, graphite, or any combination thereof may be used.

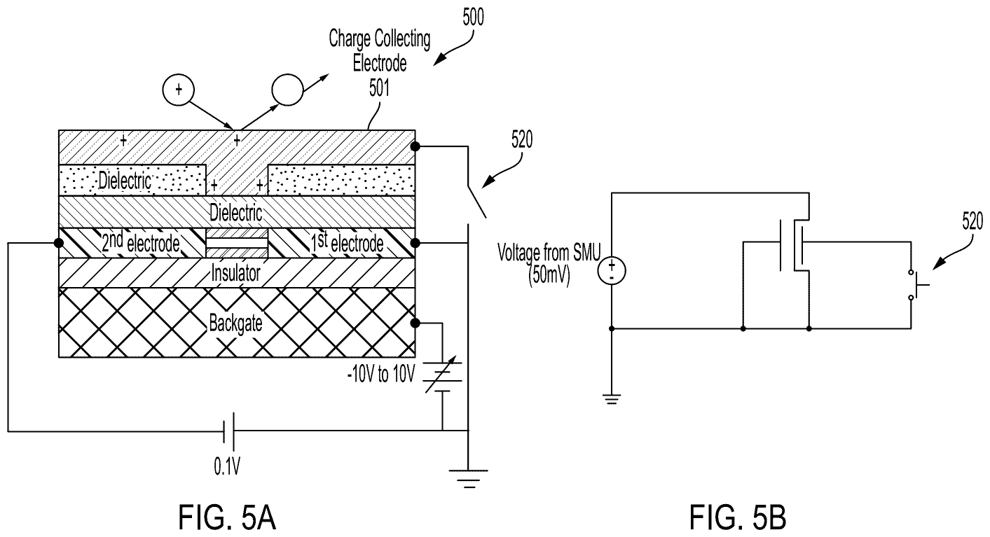

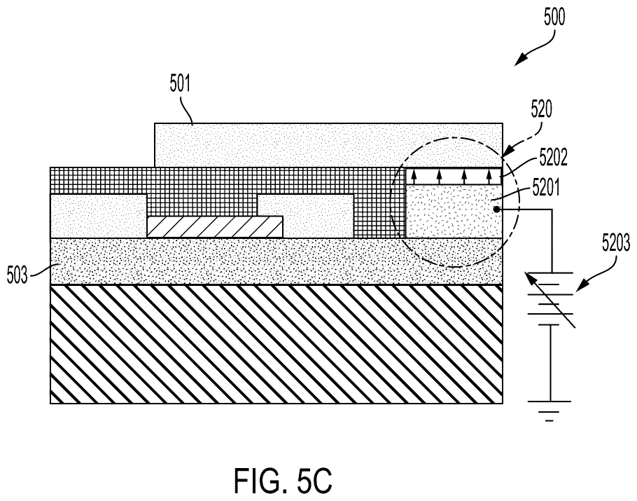

For the configuration where the top electrode floats (see, e.g., FIGS. 3 and 4), the charges accumulated in the top electrode may need to be removed occasionally or periodically. As shown in FIGS. 5A and 5B, in order to remove the charges accumulated in the top electrode 501 and to return the top electrode 501 to a specified charge state, typically to the ground potential, the top electrode 501 may be short-circuited to ground or to a specified potential via a reset switch 520. The reset switch 520 may be implemented with any desired electronic reset mechanism including, for example, a semiconductor relay, a mechanical relay, and a solid-state relay such as a high impedance low noise JFET, a reed relay, or the like. In some embodiments, the reset switch 520 may be implemented with one or more transistors, including tunneling field effect transistors which may be intrinsically implemented on the substrate or extrinsically provided using external devices.

FIG. 5C schematically shows a reset switch 520 implemented as a tunneling dielectric and electrodes similar to a floating gate transistor. For the reset function, a reset electrode 5201 and a tunneling dielectric 5202 may be fabricated within the device. In some embodiments, the reset electrode 5201 may be disposed on a first dielectric 503, and the tunneling dielectric 5202 may be disposed between the top electrode 501 (or an extension thereof) and the reset electrode 5201. With the reset switch 520, the top electrode 501 may be returned to a specified charge state through quantum mechanical tunneling of electrons or holes through the tunneling dielectric 5202. The reset electrode 5201 that is separated from the top electrode 501 by an insulator (e.g., the tunneling dielectric 5202) may be set to a voltage high or low enough to cause the charges to tunnel through the tunneling dielectric 5202. This process may return the top electrode 501 to a predetermined potential such as a ground potential. Unlike the direct grounding as shown in FIG. 5A, the top electrode 501 of FIG. 5C may return to a specified voltage that is different from the voltage of the reset electrode 5201. To this end, a variable power supply 5203 may be provided.

Alternatively or additionally, the resetting may be accomplished by UV, X-Ray, or by balancing the top electrode with opposite polarity charges incident on the top electrode, including ions or electrons if the charge is positive, or by causing electrons to tunnel into or out of the top electrode. In some embodiments, the apparatus reset may be achieved by changing the second dielectric layer to a conductive state. In various embodiments, the reset may be performed at regular time intervals and may be triggered based on a high frequency timing circuit. Alternatively or additionally, the reset may be performed whenever necessary, using some threshold signal, or manually.

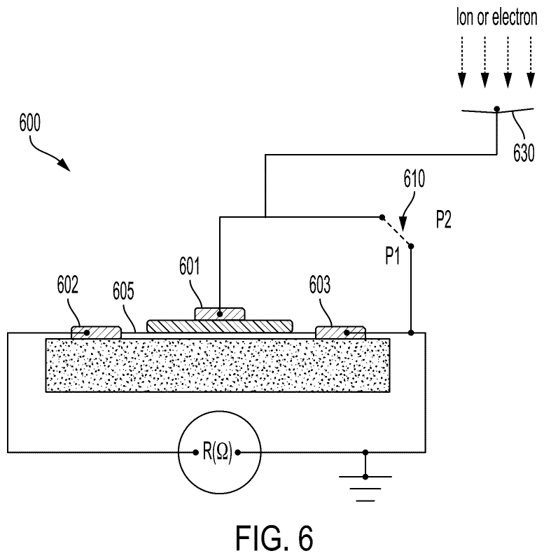

Hereinbelow, examples of electronic devices that can be implemented based on the charge sensors according to the present disclosure will be described with reference to FIGS. 6-12.

FIG. 6 schematically shows an embodiment of an electrometer based on a charge sensor according to the present disclosure. An electrometer device 600 according to an embodiment of the present disclosure, may be configured to count the total amount of incoming charges. The electrometer device 600 according to the present disclosure may count the total number of charges since it was reset, unlike a generic Faraday cup, which only measures the instantaneous rate of charge arrival. Also, the electrometer device 600 according to the present disclosure has a greater charge-to-current amplification than a generic Faraday cup. The electrometer device 600 may include a charge collector 630, which may be configured as a metal surface of chosen geometry to collect incoming charges, ions, and/or electrons. To start measuring, a switch 610 may be opened (i.e. “P2”), thereby disconnecting the charge collector 630 from the ground. Thereafter, the collected charges may be applied to a top electrode 601, and the change in electrical resistance of a channel layer 605 between a first electrode 602 and a second electrode 603 may be measured, which may be calibrated to the amount of incident charges. In order to reset the electrometer device 600, the switch 610 may be flipped to the P1 position, which is grounded.

FIG. 6 is an example illustrating the use of a remote charge detection configuration, and the electrometer according to the present disclosure is not limited to the charge sensor configuration shown in FIG. 6. In any embodiments of the charge sensor configurations, such as the embodiments shown in FIGS. 1, 3, and 4, the top electrode may be electrically connected to an external/remote charge collector similar to the charge collector 630 shown in FIG. 6 for remote charge collection.

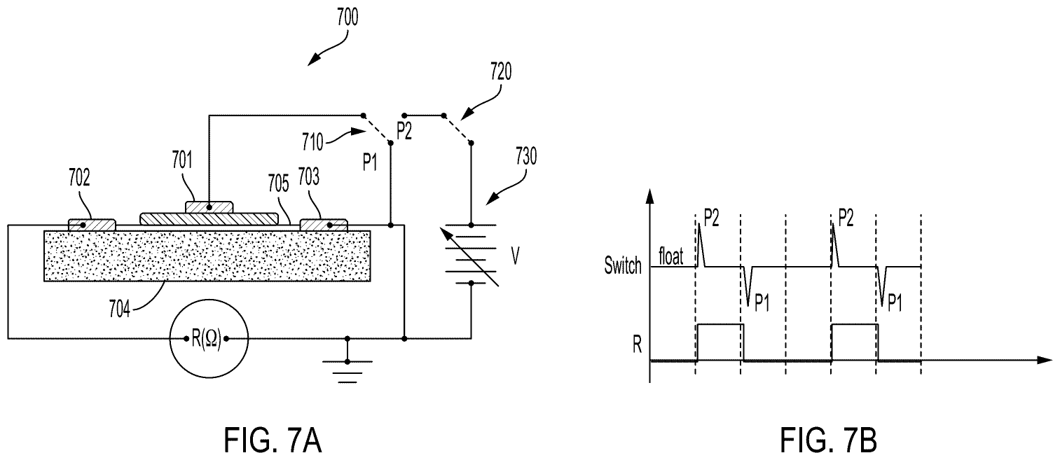

FIG. 7A schematically shows an embodiment of a memory device based on a charge sensor according to the present disclosure, and FIG. 7B illustrates switching operations for the memory device of FIG. 7A. As shown in FIG. 7A, to implement a memory device 700, the charge sensor according to the present disclosure may be configured to operate between a charged state (e.g., “1” or “on”) and a drained state (e.g., “0” or “off”). More specifically, if a first switch 710 is connected to the P2 position, which is connected to a charge (e.g., voltage) source 730, a top electrode 701 may be charged by the charge source 730. Subsequently, a second switch 720 may be opened, which would maintain the top electrode 701 at the charged state (e.g., bit value=1). At this state, if the first switch 710 is connected to the P1 position, which is grounded, the top electrode 701 may be returned to the non-charged state (e.g., bit value=0) or may be “erased.”

To read the memory state, a predetermined voltage may be applied across a first electrode 702 and a second electrode 703. As described above, if the top electrode 701 is charged, a channel layer 705 may be subject to an electric field formed between the top electrode 701 and the channel layer 705, which may increase or decrease the resistance of the channel layer 705. If the top electrode 701 is not charged, the resistance of the channel layer 705 will be lower or higher relative to the charged state. Therefore, by measuring the current response to the applied voltage between the first electrode 702 and the second electrode 703, the resistance of the channel layer 705 may be determined. It should be noted that reading the resistance does not change the charge state of the top electrode 701.

FIG. 7B illustrates that when the first switch 710 is connected to the P2 position, the resistance of the channel layer 705 (shown in the bottom panel of FIG. 7B) is increased, and when the first switch 710 is connected to the P1 position, the resistance of the channel layer 705 is decreased. The increased resistance may correspond to the bit value of 1, and the decreased resistance may correspond to the bit value of 0, or vice versa, allowing the charge sensor apparatus of the present disclosure to read and write binary data, thereby functioning as a memory device.

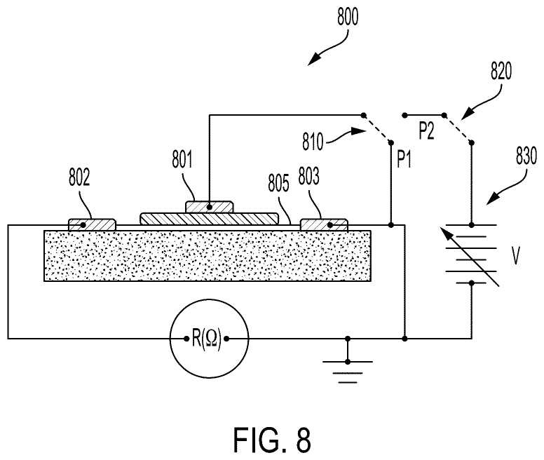

FIG. 8 schematically shows an embodiment of a passive time-tracking device based on a charge sensor according to the present disclosure. A passive time-tracking device 800 may provide an estimate of time elapsed since tracking was set to ON, without requiring any additional power for keeping track of the time duration. The passive time-tracking device 800 may be initiated/primed by charging a top electrode 801, which may be achieved by switching a first switch 810 to the P2 position and a second switch 820 to the closed position for a predetermined duration of time, such that the top electrode 801 may be connected to a charge source 830. In some embodiments, the predetermined duration of time may be the time required for the resistance between a first electrode 802 and a second electrode 803 to reach a steady value (e.g., R₀). The charge source 830 may be implemented as a battery-based charging circuit, which may or may not be a part of the actual device. When the first switch 810 is disconnected from the P2 position and maintained open, the time-tracking may be turned on. Natural or intrinsic leakage of the charges through the internal circuit may cause the charge of the top electrode 801 (and hence the voltage of the top electrode 801) to change over time, which may result in the change in the resistance of a channel layer 805 between the first electrode 802 and the second electrode 803. A pre-calibrated look-up table may be used to read the resistance and obtain an estimate of the time elapsed since the device 800 was turned on. Such a time-tracking device can be made in a small form factor, and may be included in shipments that are supposed to be delivered within a specified timeframe. The measured resistance may indicate whether the shipment took longer than the specified timeframe to arrive. Further, switching the first switch 810 to the P1 position may reset the time-tracking device 800. The process may be repeated, and accordingly, the time-tracking device 800 according to the present disclosure is reusable.

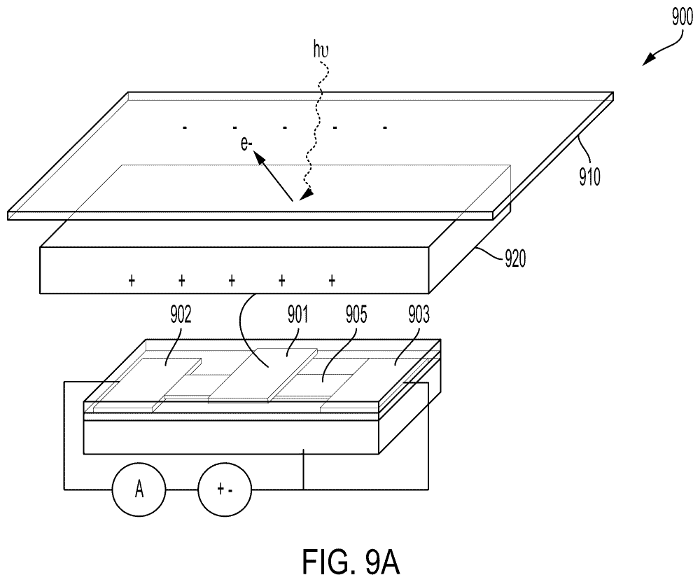

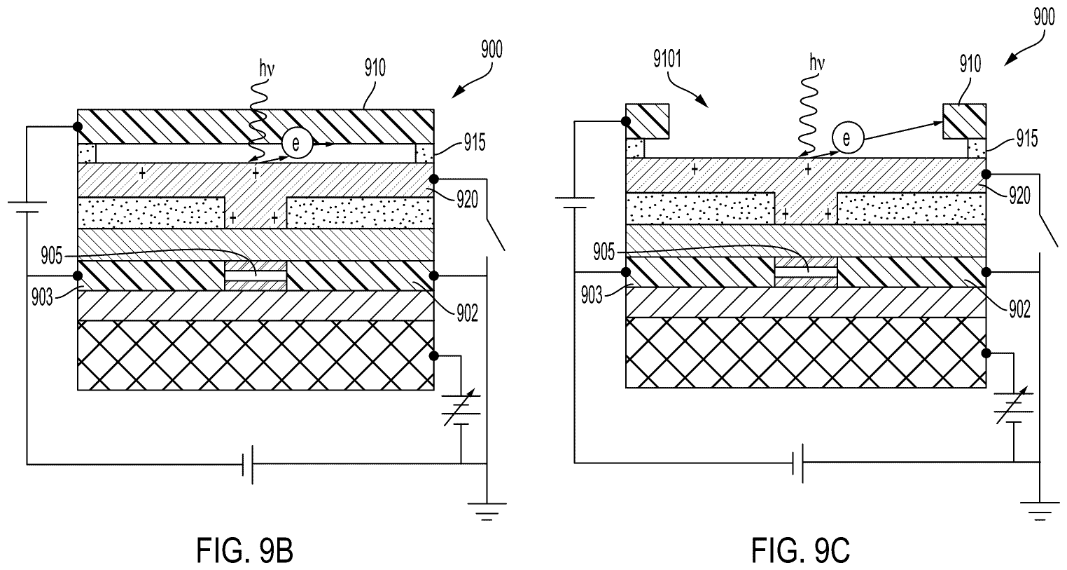

FIGS. 9A-9C schematically show embodiments of photon sensors based on the charge sensors according to the present disclosure. Referring to FIG. 9A, in some embodiments, the charge sensor apparatus according to the present disclosure may be configured to detect X-rays and/or gamma rays. For such embodiments, a photon sensor device 900 may include an anode 910 and a cathode 920. The cathode 920 may include a material having a photon cross-section that is higher than that of a material included in the anode 910. For example, the cathode 920 may have a higher atomic number (Z) than the anode 910. The anode 910 may be electrically connected to a ground or predetermined voltage. By way of example, the predetermined voltage may be about 5V.

In the photon sensor device 900 according to embodiments of the present disclosure, a photon (denoted by its energy hv) may pass through the low Z anode 910 and may interact with the high Z cathode 920, thereby emitting an electron that travels to the anode 910. In response, the cathode 920 may become positively charged. The cathode 920 may be electrically connected to a top electrode 901, allowing the charge to modulate one or more electrical properties of a channel layer 905. A predetermined voltage (e.g., about 0.1V) may be applied between a first electrode 902 and a second electrode 903, and a resulting current may be monitored. Each collected charge may be detected as a shift in the channel resistance, measured by steady state or alternating current or voltage. For example, in such a configuration, a charge-to-current amplification factor (e.g., a gain) may be between 10⁶ and 10⁸ Amps(A)/Coulomb(C) or between 10⁶ and 10⁸ Volts(V)/Coulomb(C).

In the embodiment shown in FIG. 9A, the cathode 920 and the top electrode 901 may be separately provided and may be in electrical connection therebetween. In some embodiments, as shown in FIG. 9B, the cathode 920 may be integrally formed as the top electrode and function as the top electrode as well. In some embodiments, as shown in FIG. 9C, a window 9101 may be formed in the anode 910 such that the photons can directly interact with the cathode/top electrode 920, and the anode 910 may receive the electron emitted from the cathode/top electrode 920. In this embodiment, the anode 910 may not be required to have a low photon cross-section. Such an embodiment may be better suited for vacuum enclosure environments. In the above embodiments, a spacer 915 (e.g., an insulator or a dielectric) may be disposed between the anode 910 and the cathode 920 to electrically insulate the anode 910 and the cathode 920 while mechanically supporting the structure thereof.

Similar to embodiments described above, the top electrode 901 or the cathode 920 may be wired to ground via a switch for a near instantaneous reset. Due to the integrating nature and rapid resetting capabilities, the photon sensor device 900 may mitigate the dead-time issue associated with conventional photon sensor devices such as a Geiger-Müller tube or a photomultiplier tube.

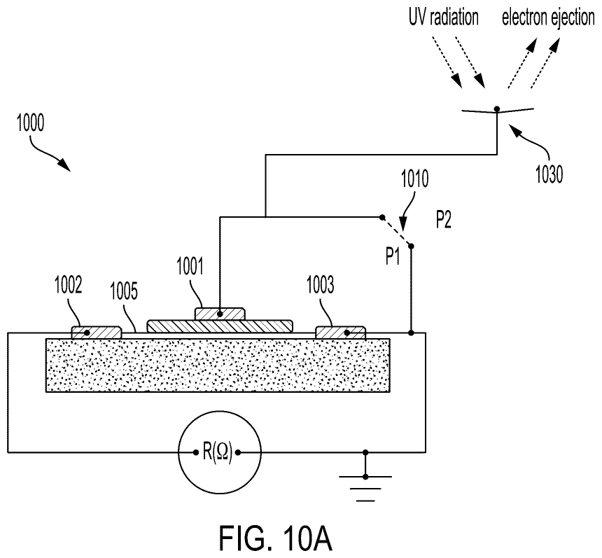

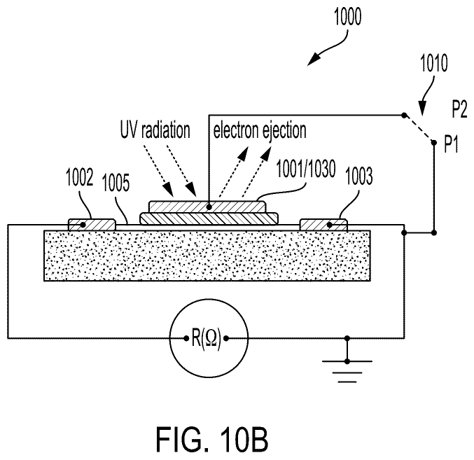

FIG. 10A schematically shows an embodiment of a UV dosimeter (herein interchangeably referred to as photometer) based on a photon sensor configuration shown in FIG. 9A, with a switch to initiate the measurement and reset the device. As described above with reference to FIG. 9A, a UV dosimeter device 1000 according to the present disclosure may utilize UV-induced charging of a photoelectric member 1030 via photoelectric effect at its surface. The type of the metal may be chosen based on the minimum photon energy of the UV light to be detected. For example, if the work function of the metal is 4.5 eV, no UV photons with photon energy below 4.5 eV will result in ejection of electrons. FIG. 10B schematically shows an embodiment of a UV dosimeter based on a photon sensor configuration shown in FIG. 9B or 9C, in which the top electrode 1001 also serves as the photoelectric member 1030.

To operate the UV dosimeter device 1000, a switch 1010 may be opened (i.e., “P2”). Thereafter, incident UV photons may result in a change in charging of a top electrode 1001. A constant or time-varying voltage may be applied between a first electrode 1002 and a second electrode 1003, and the resistance of a channel layer 1005 may be measured from the current between the first electrode 1002 and the second electrode 1003. In some implementations, a constant or time-varying current may be applied between the first electrode 1002 and the second electrode 1003, and the resistance of the channel layer 1005 may be measured from the voltage between the first electrode 1002 and the second electrode 1003. The incident photons may be quantified based on the change in the resistance of the channel layer 1005, and the total dose of UV incident on the metal sheet may be quantified. To reset the UV dosimeter device 1000, the first switch 1010 may be connected to the P1 position, which is grounded.

The UV dosimeter according to the present disclosure is not limited to the charge sensor configurations shown in FIGS. 10A and 10B. In any embodiments of the charge sensor configurations, such as the embodiments shown in FIGS. 1, 3, and 4, the top electrode may be electrically connected to an external/remote photometric charge collector configuration similar to the ones shown in FIG. 10A for remote sensing. Alternatively, the top electrode may be made integrally as the same electrode as the photocathode as shown in FIG. 10B.

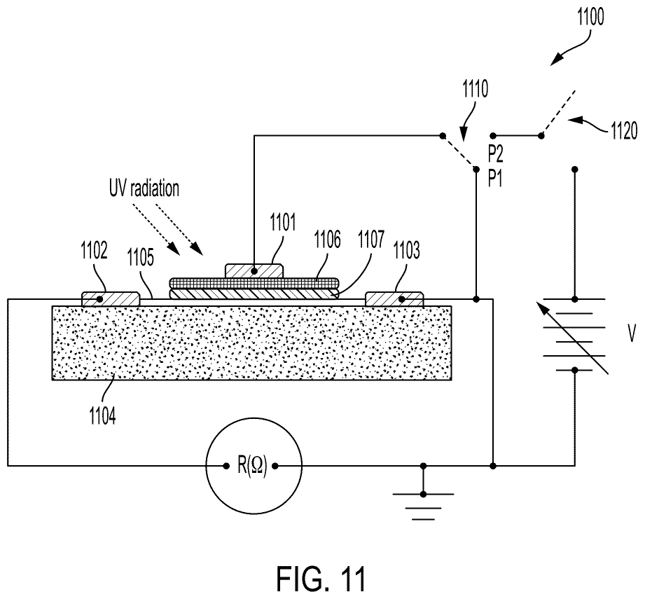

FIG. 11 schematically shows a related embodiment of a UV dosimeter based on a charge sensor according to the present disclosure. In a UV detector device 1100 shown in FIG. 11, a first switch 1110 may be connected to the P2 position, and a second switch 1120 may be closed, which allows a top electrode 1101 to be initially charged. A constant or time-varying voltage or current may be applied between a first electrode 1102 and a second electrode 1103, and the resistance of a channel layer 1105 between the first electrode 1102 and the second electrode 1103 prior to the UV exposure may be measured. In this embodiment, a dielectric layer 1106 may include a UV sensitive semiconductor, such as SiC, TiO₂, ZnO, GaO, P3HT, MEH-PPV, semiconducting polymers, diamond, fullerene, BN, AlP, AlAs, GaN, AlGaN, InGaN, InAlGaN, GaP, CdS, CdSe, CdTe, ZnSe, ZnS, ZnTe, Cu₂O, or other wide band gap material, that forms a Schottky junction with the top electrode 1101 metal. In this embodiment, a thin insulator or air/vacuum gap 1107 may be disposed between the dielectric layer 1106 and the channel layer 1105.

To start measuring the UV dose, the second switch 1120 may be opened, while the first switch 1110 remains connected to the P2 position or connected to neither the P2 position nor the P1 position (i.e., “open”). As UV light is incident, the dielectric layer 1106 may generate a UV-induced charge in the top electrode 1101, which may change the charging state of the channel layer 1105. In some embodiments, the channel layer 1105 may include a graphene sheet. The changed charging state of the channel layer 1105 may be monitored by measuring the resistance between the first electrode 1102 and the second electrode 1103, which may be quantified to provide an instantaneous detection of UV photons. To reset the UV detector device 1100, the first switch 1110 may be moved to the P1 position, which is grounded.

In some embodiments, the dielectric layer 1106 may be implemented as an insulator, and a UV sensitive semiconductor layer may be disposed above the top electrode 1101. In such a configuration, the UV sensitive semiconductor layer does not form a second junction with the channel layer 1105, and thus, instead of the charging state of the channel layer 1105 being changed, an electric field may be created between the top electrode 1101 and the channel layer 1105, which may change the resistance of the channel layer 1105.

By way of example, the UV dosimeter according to the present disclosure may be configured to detect UV-C emissions from a hypersonic flying object while being blind against the solar radiation in the UV-A/B, visible, and NIR bands. The UV dosimeters can serve as a UV-C detector for early warning systems and hypersonic object detection systems.

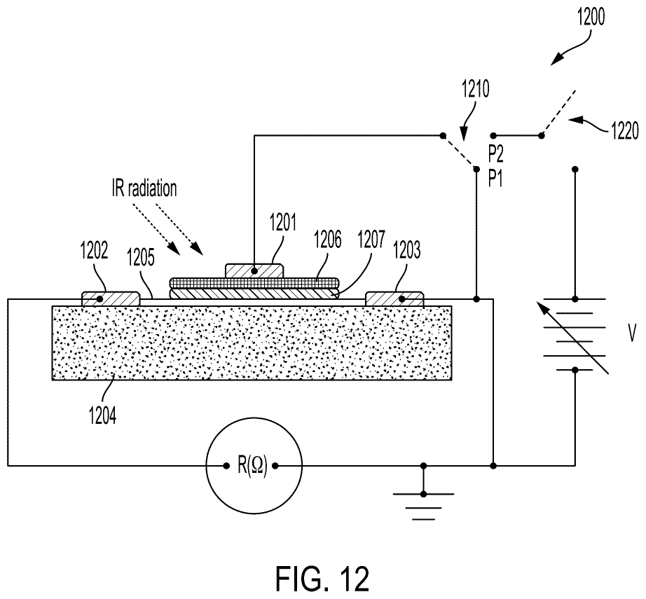

FIG. 12 schematically shows an embodiment of an infrared (IR) radiation and/or other wavelength dosimeter based on a charge sensor according to the present disclosure. An IR detector device 1200 shown in FIG. 12 may include similar structures as the UV dosimeter device 1100 shown in FIG. 11, but may include different light-sensitive semiconductor material that responds to the IR or other wavelength of interest. In the IR detector device 1200 shown in FIG. 12, a first switch 1210 may be connected to the P2 position, and a second switch 1220 may be closed to initially charge a top electrode 1201. A constant or time-varying voltage or current may be applied across a first electrode 1202 and a second electrode 1203, and the resistance of a channel layer 1205 may be measured between the first electrode 1202 and the second electrode 1203 prior to the IR exposure. A dielectric layer 1206 may include an IR sensitive semiconductor, such as InN, InP, InO, InSb, SnO₂, InGaAs, GaAs, GaSb, InAs, Ge, InGaAs, PbS, PbTe, PbSe, Ge, Si, or other narrow band gap material, that forms a Schottky junction with the top electrode 1201. In this embodiment, an insulator or air/vacuum gap 1207 may be disposed between the dielectric layer 1206 and the channel layer 1205.

To start the IR measurement, the second switch 1220 may opened, and/or the first switch 1210 may be disconnected from both the P1 position and the P2 position. When IR light is incident, the IR sensitive semiconductor may generate an IR-induced charge on the top electrode 1201 metal, which may change the charging state of the channel layer 1205. Due to the change of the charging state, the resistance of the channel layer 1205 may be changed, which may be detected by measuring the current or voltage between the first electrode 1202 and the second electrode 1203. To reset the device, the first switch 1210 may be moved the P1 position, which is grounded.

In some embodiments, the dielectric layer 1206 may be implemented as an insulator, and the IR sensitive semiconductor layer may be disposed above the top electrode 1201. In such a configuration, the IR sensitive semiconductor layer does not form a second junction with the channel layer 1205, and thus, instead of changing the charging state of the channel layer 1205, the incident IR photons may create an electrical field between the top electrode 1201 and the channel layer 1205, which may change the resistance of the channel layer 1205 therebetween. In some embodiments, the IR sensitive semiconductor layer may be replaced with another material that is known to respond to a particular wavelength range of light of interest.

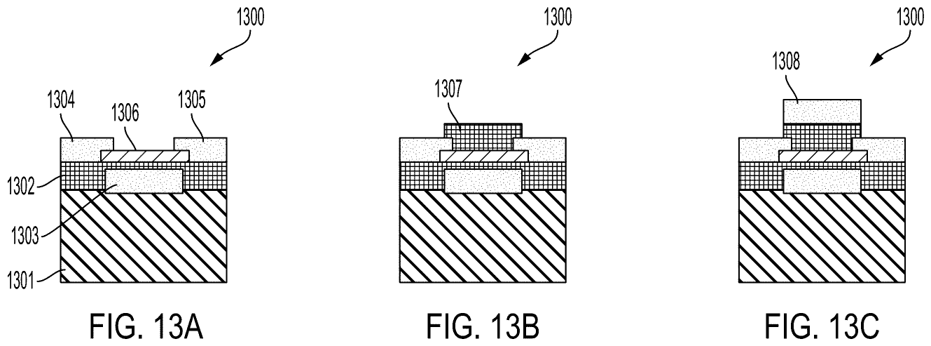

The configuration of the charge sensor according to the present disclosure may be variously modified without departing from the scope of the present disclosure. For example, the charge storage layer may be disposed under the channel layer. Such examples are shown in FIGS. 13A-13C.

Referring to FIG. 13A, a charge sensor 1300 according to an embodiment of the present disclosure may include a substrate 1301, and a lower dielectric layer 1302 disposed on the substrate 1301. A channel layer 1306 may be disposed on the lower dielectric layer 1302, the channel layer 1306 being in electrical connection with a first electrode 1304 and a second electrode 1305. In particular, a back electrode 1303 may be disposed between the substrate 1301 and the lower dielectric layer 1302, where the back electrode 1303 may be electrically connected to an external source of one or more charges, for example, to a charge collector such as the one shown in FIG. 6. Accordingly, the one or more charges introduced on the back electrode 1303 from the charge collector may alter one or more electrical properties of the channel layer 1306, and the charges on the back electrode 1303 may be quantified by detecting changes in the electrical properties of the channel layer 1306.

Referring to FIG. 13B, in some embodiments, a dielectric encapsulation layer 1307 may be disposed on the channel layer 1306. Further, as shown in FIG. 13C, a top electrode (e.g., a third electrode) 1308 may be disposed on the dielectric encapsulation layer 1307. In such embodiments, the top electrode 1308 may function similarly as the back electrode 302 of the embodiment shown in FIG. 3. In these configurations, at least one of the back electrode 1303 or the top electrode 1308 may function as the charge storage layer, which may induce the change in electrical properties in the channel layer 1306. When the back electrode 1303 is used as the charge storage layer, since it may be difficult to expose it in the path of directly incident charges, it may be used in the remote sensing configuration by being connected to an external charge collector.

Aspects of the present disclosure also include a method of quantifying ion flux using various embodiments of charge sensors according to the present disclosure. More particularly, the method may include allowing one or more charges to be introduced on the top electrode (e.g., the third electrode) due to the ion flux; applying a driving voltage or current between the first electrode and the second electrode; and measuring a change in one or more electrical properties of the channel layer caused by the one or more charges of the third electrode, thereby quantifying the ion flux. By way of example, the one or more electrical properties of the channel layer may include electrical resistance, impedance, or the like.

In some embodiments, a similar method may be applied for quantifying electron flux. More particularly, the method may include allowing one or more charges to be introduced on the top electrode (e.g., third electrode) due to the electron flux; applying a driving voltage or current between the first electrode and the second electrode; and measuring a change in one or more electrical properties of the channel layer caused by the one or more charges on the third electrode, thereby quantifying the electron flux.

In some embodiments, a similar method may be applied for quantifying photon flux. More particularly, the method may include allowing one or more charges to be introduced on the top electrode (e.g., third electrode) due to electrons being ejected by the photoelectric effect caused by the photon flux; applying a driving voltage or current between the first electrode and the second electrode; measuring a change in one or more electrical properties of the channel layer caused by the one or more charges on the third electrode, thereby quantifying the one or more charges; and quantifying the photon flux based on photoelectric quantum yield.

### Experiment

Hereinbelow, experimental measurement data using the charge sensor apparatus according to embodiments of the present disclosure will be presented.

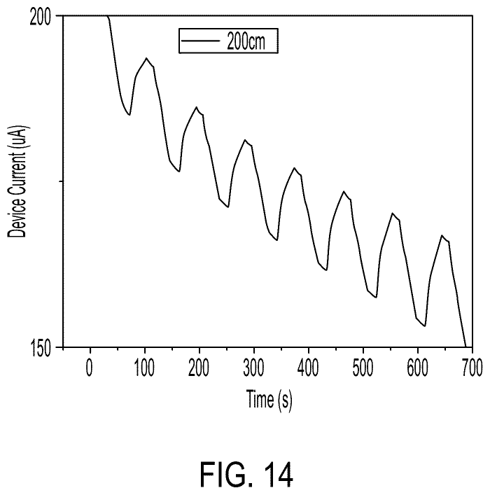

FIG. 14 shows experimental results for measuring the current response of a charge sensor according to the present disclosure using corona discharge ion sources. In this experiment, two corona discharge ion sources, one positive and one negative, were placed 200 cm from the device and pointed at the device. In each cycle, the positive ion source was turned on for 30 seconds, all ion sources were turned off for 15 seconds, the negative ion source was turned on for 30 seconds, all ion sources were turned off for 15 seconds, and then the cycle was repeated. FIG. 14 shows the resultant current flowing through the channel layer between the first electrode and the second electrode, and it clearly distinguishes the period during which the positive ion source was turned on (indicated by the upward slopes of the curve) and during which the negative ion source was turned on (indicated by the downward slopes of the curve).

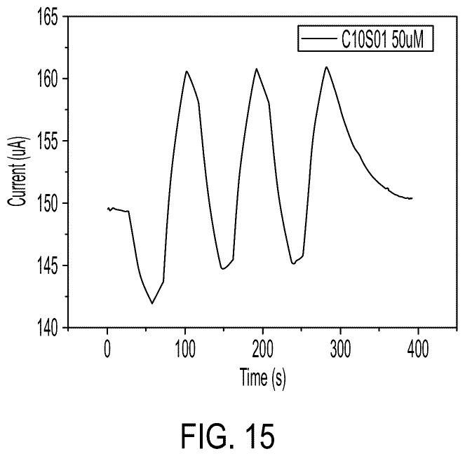

FIG. 15 shows experimental results for measuring the current response of a charge sensor according to the present disclosure to corona discharge ion sources using a separate charge collector connected to the top electrode, similar to an embodiment shown in FIG. 6. Two corona discharge ion sources, one positive and one negative, were placed 200 cm from a Faraday cup and pointed towards the Faraday cup. The Faraday cup was wired to the top electrode of the charge sensor apparatus, and the surrounding metal plate was grounded. In each cycle, the positive ion source was turned on for 30 seconds, all ion sources were turned off for 15 seconds, the negative ion source was turned on for 30 seconds, all ion sources were turned off for 15 seconds, and then the cycle was repeated. FIG. 15 shows the response of the current flowing through the channel layer between the first electrode and the second electrode, and it clearly delineates the period during which the positive ion source was turned on (indicated by the upward slopes of the curve) and during which the negative ion source was turned on (indicated by the downward slopes of the curve).

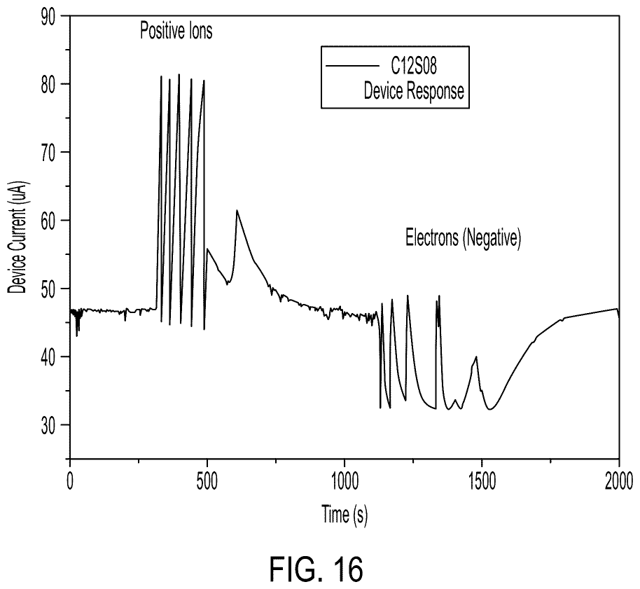

FIG. 16 shows experimental results for measuring the current response of a charge sensor according to the present disclosure to vacuum chamber ions and electrons generated by a controlled charge source. The charge source was manually controlled to either produce ions or electrons. The current flowing through the channel layer was measured, and the top electrode was occasionally grounded to reset the charge thereof.

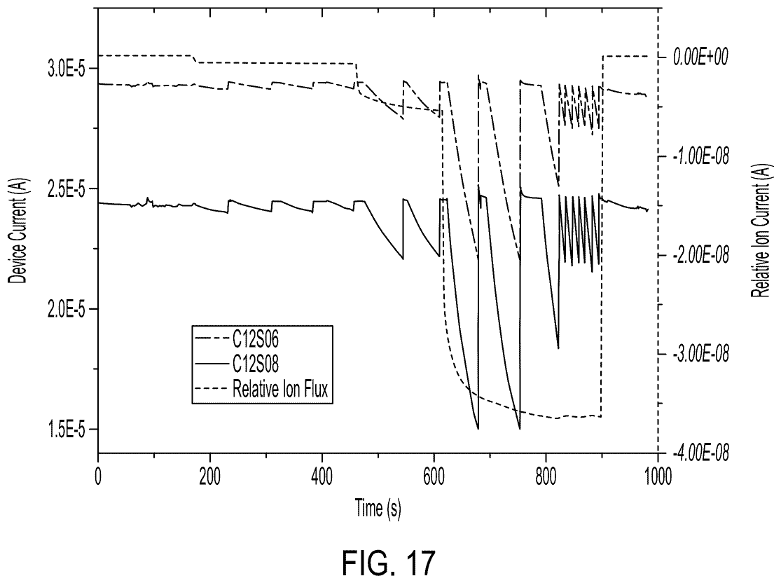

FIG. 17 shows experimental results comparing the current responses of a charge sensor according to the present disclosure to positive ion flux with the current generated by the ion flux at the collector electrode of the ion source. The ion source was manually controlled to produce ions in increasing amounts, the current flowing through the channel layer was measured, and the top electrode was occasionally grounded to reset the charge thereof. The collector current of the ion source was measured and also presented in the plot to provide a relative measure of ions incident on the top electrode. FIG. 17 demonstrates higher deflection angles with higher ion flux, which indicates that the channel layer current responds to the incident ion flux as expected.

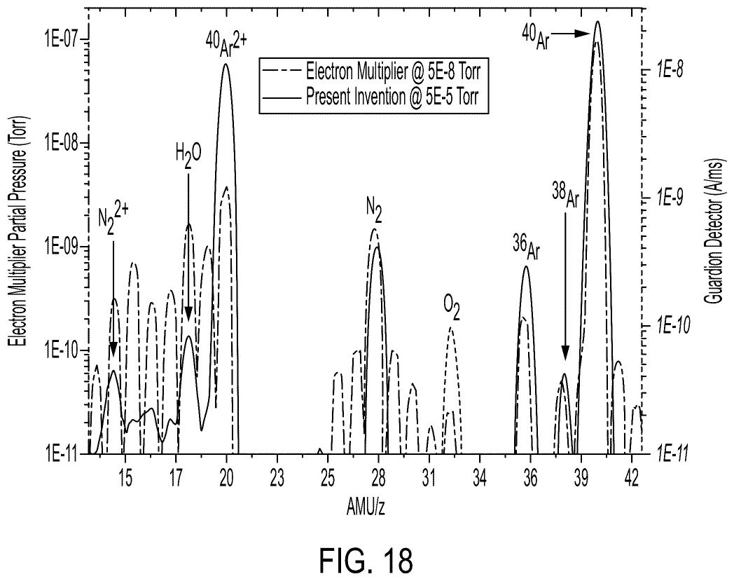

FIG. 18 shows experimental results comparing the response of a charge sensor according to the present disclosure with that of a commercial electron multiplier within a residual gas analyzer. A quadrupole mass-to-charge filter residual gas analyzer was operated in a manner that scanned through mass-to-charge ratios from 0 to 64 AMU/Z, and at the other end either the charge sensor according to the present disclosure or the built-in electron multiplier were positioned to measure charge. The signals generated demonstrate that the charge sensor according to the present disclosure can function in a manner similar to that of commercial charge sensors, under the same measurement conditions. Notably, the built-in electron multiplier required 1000 V or more for the driving voltage whereas the charge sensor according to the present disclosure was operated at around 0.1 V.

The experimental results demonstrated that the charge sensors according to the present disclosure can achieve high sensitivity (e.g., about one million times amplification compared to the built-in electron multiplier) at significantly lower voltage (e.g., about 10,000 times lower voltage) or power. Further, the charge sensors according to the present disclosure do not require high vacuum, eliminating the need for heavy and power-consuming turbomolecular pumps. These advantages can solve the portability issues on instruments such as mass spectrometers and eliminate pressure differential systems on various analytical tools.

Hereinabove, although the present disclosure is described by specific matters such as concrete components, and the like, the exemplary embodiments and the drawings are provided merely for assisting in the entire understanding of the present disclosure. Therefore, the present disclosure is not limited to the exemplary embodiments described herein. Various modifications and changes can be made by a person of ordinary skill in the art to which the present disclosure pertains. The spirit of the present disclosure should not be limited to the above-described exemplary embodiments, and the following claims as well as all technical spirits modified equally or equivalently to the claims should be interpreted to fall within the scope and spirit of the disclosure.

What is claimed is:

1. An apparatus comprising:
a substrate;
a first electrode and a second electrode;
a channel layer disposed on the substrate and in electrical connection with the first electrode and the second electrode; and
a charge storage layer disposed on or above the channel layer,
wherein one or more charges introduced on the charge storage layer are configured to alter one or more electrical properties of the channel layer.

2. The apparatus of claim 1, wherein the charge storage layer comprises a dielectric layer.

3. The apparatus of claim 2, wherein the dielectric layer comprises Al₂O₃, SiO₂, Si₃N₄, ZrO₂, HfO₂, TiO₂, SrTiO₃, CaTiO₃, SiC, GaN, TiO₂, ZnO, diamond, fullerene, BN, Be₃N₂, AlP, AlAs, AlGaN, GaP, CdS, ZnSe, ZnS, ZnTe, Cu₂O, SnO₂, polydimethylsiloxane (PDMS), polymethyl methacrylate (PMMA), polyethylene terephthalate (PET), polyethylene (PE), polypropylene (PP), or any combination thereof.

4. The apparatus of claim 2, wherein a thickness of the dielectric layer is equal to or less than about 100 nm.

5. The apparatus of claim 2, wherein the one or more charges on the charge storage layer is configured to be removed via heat, UV light, oppositely charged ions, electron or hole tunneling, or electron beams.

6. The apparatus of claim 1, wherein the charge storage layer comprises a light-sensitive material, which becomes conductive in response to one or more photons being incident thereto.

7. The apparatus of claim 6, wherein the light-sensitive material includes SiC, TiO₂, ZnO, GaO, P3HT, MEH-PPV, semiconducting polymers, diamond, fullerene, BN, AlP, AlAs, GaN, AlGaN, InGaN, InAlGaN, InN, InP, InO, InSb, GaP, CdS, CdSe, ZnSe, ZnS, ZnTe, Cu₂O, SnO₂, InGaAs, GaAs, InAs, Ge, InGaAs, PbS, PbTe, PbSe, Ge, Si, or any combination thereof.

8. The apparatus of claim 1, wherein the charge storage layer comprises:
an upper dielectric layer disposed on the channel layer; and
a third electrode disposed on the upper dielectric layer.

9. The apparatus of claim 8, wherein the third electrode is configured to be reset by being connected to a predetermined voltage via a switch.

10. The apparatus of claim 9, wherein the predetermined voltage is a ground voltage.

11. The apparatus of claim 9, wherein the switch is implemented as a transistor.

12. The apparatus of claim 9, further comprising:
a reset electrode; and
a tunneling dielectric disposed between the third electrode and the reset electrode,
wherein the predetermined voltage is set on the reset electrode to allow the third electrode to be reset.

13. The apparatus of claim 8, wherein the third electrode is electrically connected to an external source or collector of the one or more charges.

14. The apparatus of claim 8, wherein the upper dielectric layer is sensitive to ultraviolet (UV) light.

15. The apparatus of claim 14, wherein the upper dielectric layer comprises SiC, TiO₂, ZnO, GaO, P3HT, MEH-PPV, semiconducting polymers, diamond, fullerene, BN, AlP, AlAs, GaN, AlGaN, InGaN, InAlGaN, GaP, CdS, CdSe, ZnSe, ZnS, ZnTe, Cu₂O, or any combination thereof.

16. The apparatus of claim 8, wherein the upper dielectric layer is sensitive to infrared (IR) light.

17. The apparatus of claim 16, wherein the upper dielectric layer comprises InN, InP, InO, InSb, SnO₂, InGaAs, GaAs, InAs, Ge, InGaAs, PbS, PbTe, PbSe, Ge, Si, or any combination thereof.

18. The apparatus of claim 8, wherein an area of the third electrode is larger than an area of the channel layer.

19. The apparatus of claim 1, wherein the substrate comprises a lower dielectric layer that is disposed under the channel layer.

20. The apparatus of claim 19, wherein the substrate further comprises a conductive or semiconductive layer disposed under the lower dielectric layer.

21. The apparatus of claim 20, wherein the conductive or semiconductive layer is subject to a predetermined voltage.

22. The apparatus of claim 21, wherein the predetermined voltage is a ground potential.

23. The apparatus of claim 1, further comprising:
a dielectric encapsulation layer disposed over the first electrode and the second electrode to insulate them from the one or more charges.

24. The apparatus of claim 23, wherein the dielectric encapsulation layer does not cover the charge storage layer.

25. The apparatus of claim 24, further comprising:
a conductive layer disposed on the dielectric encapsulation layer to provide electrical grounding.

26. The apparatus of claim 1, wherein the one or more charges introduced on the charge storage layer is configured to induce charges in the channel layer, thereby altering the one or more electrical properties thereof.

27. The apparatus of claim 1, wherein a constant or time-varying voltage is applied across the first electrode and the second electrode, and
wherein a resulting current is measured across the first electrode and the second electrode to detect a change in the one or more electrical properties of the channel layer.

28. The apparatus of claim 27, wherein the one or more charges introduced on the charge storage layer are quantified based on the change in the one or more electrical properties of the channel layer.

29. The apparatus of claim 1, wherein a constant or time-varying current is applied across the first electrode and the second electrode, and
wherein a resulting voltage is measured across the first electrode and the second electrode to detect a change in the one or more electrical properties of the channel layer.

30. The apparatus of claim 29, wherein the one or more charges introduced on the charge storage layer are quantified based on the change in the one or more electrical properties of the channel layer.

31. The apparatus of claim 1, wherein the channel layer is formed of a metallic, semi-metallic, or semiconductor material.

32. The apparatus of claim 31, wherein the channel layer is formed of a nanomaterial.

33. The apparatus of claim 32, wherein the nanomaterial includes graphene, single-walled carbon nanotube (SWNT), semiconductor SWNT, metallic SWNT, mixed SWNT, multi-walled carbon nanotube (MWNT), semiconductor MWNT, metallic MWNT, mixed MWNT, semiconductor nanowires, Si, graphdiyne, borophene, silicene, MoS₂, WS₂, MoSe₂, WSe₂, MoTe₂, MXene, or any combination thereof.

34. The apparatus of claim 1, wherein the one or more charges occur due to addition or removal of an electron, a positive ion, a negative ion, a photon, or any combination thereof; or due to a radioactive, nuclear, chemical, electrochemical, photochemical, and/or photoelectrochemical process resulting in charged particles.

35. The apparatus of claim 1, further comprising:
an anode and a cathode,
wherein, in response to one or more photons being incident to the apparatus, the cathode is positively charged and liberated electrons are captured by the anode, and
wherein the cathode or the anode is electrically connected to the charge storage layer to allow the charge storage layer to become positively or negatively charged, which is quantified based on a change in the one or more electrical properties of the channel layer.

36. The apparatus of claim 35, wherein the anode and the cathode are provided separately from the substrate while being in electrical connection with the charge storage layer.

37. The apparatus of claim 1, further comprising:
a charge collector that is in electrical connection with the charge storage layer to receive the one or more charges and transmit the charges to the charge storage layer,
wherein the charge collector is provided separately from the substrate while being in electrical connection with the charge storage layer.

38. An electrometer comprising the apparatus of claim 1.

39. A memory device comprising the apparatus of claim 1.

40. A time-tracking device comprising the apparatus of claim 1.

41. A UV-C detection device comprising the apparatus of claim 1.

42. A method of quantifying ion flux using an apparatus comprising a first electrode, a second electrode, a channel layer electrically connected between the first electrode and the second electrode, and a charge storage layer disposed over the channel layer, the method comprising:
allowing one or more charges to be introduced on the charge storage layer due to the ion flux;
applying a voltage or a current between the first electrode and the second electrode; and
measuring a change in one or more electrical properties of the channel layer caused by the one or more charges on the charge storage layer, thereby quantifying the ion flux.

43. A method of quantifying electron flux using an apparatus comprising a first electrode, a second electrode, a channel layer electrically connected between the first electrode and the second electrode, and a charge storage layer disposed over the channel layer, the method comprising:
allowing one or more charges to be introduced on the charge storage layer due to the electron flux;
applying a voltage or a current between the first electrode and the second electrode; and
measuring a change in one or more electrical properties of the channel layer caused by the one or more charges on the charge storage layer, thereby quantifying the electron flux.

44. A method of quantifying photon flux using an apparatus comprising a first electrode, a second electrode, and channel layer electrically connected between the first electrode and the second electrode, and a charge storage layer disposed over the channel layer, the method comprising:
allowing one or more charges to be introduced on the charge storage layer due to electrons ejected by photoelectric effect caused by the photon flux;
applying a voltage or a current between the first electrode and the second electrode;
measuring a change in one or more electrical properties of the channel layer caused by the one or more charges on the charge storage layer, thereby quantifying the one or more charges; and
quantifying the photon flux based on photoelectric quantum yield.

45. An apparatus comprising:
a substrate;
a lower dielectric layer disposed on the substrate;
a channel layer disposed on the lower dielectric layer;
a first electrode and a second electrode that are in electrical connection with both ends of the channel layer; and
a back electrode disposed between the substrate and the lower dielectric layer,
wherein the back electrode is electrically connected to an external source of one or more charges,
wherein the one or more charges introduced on the back electrode are configured to alter one or more electrical properties of the channel layer, and
wherein the one or more charges on the back electrode are configured to be quantified based on a change in the one or more electrical properties of the channel layer.
